(19) United States
(12) Patent Application Publication
(10) Pub. No.: US 2025/0266629 A1
(43) Pub. Date: Aug. 21, 2025

(54) METHOD FOR ELECTRICALLY CONNECTING ELECTRONIC COMPONENTS OF A BATTERY SYSTEM AND BATTERY SYSTEM

(71) Applicant: SAMSUNG SDI CO., LTD., Yongin-si (KR)

(72) Inventor: Ilya GOMBATS, Graz (AT)

(21) Appl. No.: 18/975,209

(22) Filed: Dec. 10, 2024

(30) Foreign Application Priority Data
Feb. 15, 2024 (EP) 24157804.6

(51) Int. Cl. H01R 12/62; H01M 10/42; H01M 50/249; H01M 50/284; H01R 12/70; H05K 1/11; H05K 3/36

(52) U.S. Cl. CPC H01R 12/62; H01M 10/425; H01M 50/284; H01R 12/707; H05K 1/115; H05K 3/363; H01M 2010/4271; H01M 50/249; H05K 2201/10318

(57) ABSTRACT

A method for electrically connecting a first electronic component of a battery system with a second electronic component of the battery system is provided. The first electronic component includes a flexible printed circuit (FPC) including: a pin formed by folding a connection portion of the FPC; and a conductive strip on an outer surface of the folded connection portion. The second electronic component includes a printed circuit board (PCB) having a through-hole configured to receive the pin of the FPC and includes an electrically conductive plating adjacent to the through-hole. The method includes: attaching the FPC to a first side of the PCB such that the pin of the FPC is received in the through-hole in the PCB; and soldering the pin of the FPC to the conductive plating on the PCB to electrically interconnect the FPC and the PCB.

### CROSS-REFERENCE TO RELATED APPLICATION

The present application claims priority to and the benefit of European Patent Application No. 24157804.6, filed on Feb. 15, 2024, in the European Patent Office, the entire disclosure of which is incorporated herein by reference.

### BACKGROUND

### 1. Field

Aspects of embodiments of the present disclosure relate to a method for electrically connecting electronic components of a battery system and a battery system.

### 2. Description of the Related Art

Recently, vehicles for transportation of goods and peoples have been developed that use electric power as a source for motion. Such an electric vehicle is an automobile that is propelled, permanently or temporarily, by an electric motor using energy stored in rechargeable (or secondary) batteries. An electric vehicle may be solely powered by batteries (a so-called Battery Electric Vehicle or BEV) or may include a combination of an electric motor and, for example, a conventional combustion engine (a so-called Plugin Hybrid Electric Vehicle or PHEV). BEVs and PHEVs use high-capacity rechargeable batteries, which are designed to provide power for propulsion for sustained periods of time.

Generally, a rechargeable (or secondary) battery cell includes an electrode assembly including a positive electrode, a negative electrode, and a separator interposed between the electrodes. A solid or liquid electrolyte allows movement of ions during charging and discharging of the battery cell. The electrode assembly is located (or accommodated) in a casing and electrode terminals, which are positioned on the outside of the casing, establish an electrically conductive connection to the electrodes of the electrode assembly. The casing may have, for example, a cylindrical or rectangular shape.

A battery module is formed of a plurality of battery cells connected together in series or in parallel. For example, the battery module is formed by interconnecting the electrode terminals of the plurality of battery cells in a number and/or configuration depending on a desired amount of power and to realize a high-power rechargeable battery.

Battery modules can be constructed in either a block design or in a modular design. In the block design, each battery cell is coupled to a common current collector structure and a common battery management system, and the unit thereof is arranged in a housing. In the modular design, pluralities of battery cells are connected together to form submodules, and several submodules are connected together to form the battery module. In automotive applications, battery systems generally include a plurality of battery modules connected in series to provide a desired voltage.

A battery pack is a set of any number of (usually identical) battery modules or single battery cells. The battery modules, and respectively the battery cells therein, may be configured in a series, parallel, or a mixture of both to provide the desired voltage, capacity, and/or power density. Components of a battery pack include the individual battery modules and the interconnects, which provide electrical conductivity between the battery modules.

A battery system may include a battery management system (BMS), which is any suitable electronic system that is configured to manage the rechargeable battery cell, battery module, and battery pack, such as by protecting the batteries from operating outside their safe operating area, monitoring their states, calculating secondary data, reporting that data, controlling its environment, authenticating it, and/or balancing it. For example, the BMS may monitor the state of the battery cell as represented by voltage (e.g., a total voltage of the battery pack or battery modules and/or voltages of individual battery cells), temperature (e.g., an average temperature of the battery pack or battery modules, coolant intake temperature, coolant output temperature, and/or temperatures of individual battery cells), coolant flow (e.g., flow rate and/or cooling liquid pressure), and current. Additionally, the BMS may calculate values based on the above parameters, such as minimum and maximum cell voltage, state of charge (SOC) or depth of discharge (DOD) to indicate the charge level of the battery cell, state of health (SOH; a variously-defined measurement of the remaining capacity of the battery cell as % of the original capacity), state of power (SOP; the amount of power available for a defined time interval given the current power usage, temperature, and other conditions), state of safety (SOS), maximum charge current as a charge current limit (CCL), maximum discharge current as a discharge current limit (DCL), and internal impedance of a cell (to determine open circuit voltage).

The BMS may be centralized, meaning that a single controller is connected to the battery cells through a multitude of wires. In other examples, the BMS may be distributed, meaning that a BMS board is installed at each cell, and only a single communication cable extends between the battery cell and a controller. In yet other examples, the BMS may have a modular construction including a few controllers, each handling a certain number of (e.g., a group of) cells, while communicating between the controllers. Centralized BMSs are most economical but are least expandable and are plagued by a multitude of wires. Distributed BMSs are the most expensive but are simplest to install and offer the cleanest and simplest assembly. Modular BMSs provide a compromise of the features and drawbacks of the other two topologies.

The BMS may protect the battery pack from operating outside its safe operating area. Operation outside the safe operating area may be indicated by over-current, over-voltage (e.g., during charging), over-temperature, under-temperature, over-pressure, and ground fault or leakage current detection. The BMS may prevent the battery from operating outside its safe operating parameter by including an internal switch (e.g., a relay or solid-state device) that opens if the battery is operated outside its safe operating parameters, requesting the devices to which the battery is connected to reduce or even terminate using the battery, and actively controlling the environment, such as through heaters, fans, air conditioning, and/or liquid cooling.

A static control of battery power output and charging may not be sufficient to meet the dynamic power demands of various electrical consumers connected to the battery system. Thus, steady exchange of information occurs between the battery system and the controllers of the electrical consumers. This information includes the battery system's actual state of charge (SoC), potential electrical performance, charging ability, and internal resistance as well as actual or predicted power demands or surpluses of the consumers. Therefore, battery systems usually include the above-mentioned BMS for obtaining and processing such information on a system level and may include a plurality of battery module managers (BMMs), which are part of the system's battery modules and obtain and process relevant information on a module level. For example, the BMS usually measures the system voltage, the system current, the local temperature at different places inside the system housing, and the insulation resistance between live components and the system housing, while the BMMs usually measure the individual cell voltages and temperatures of the battery cells in a battery module.

Thus, the BMS is provided to manage the battery pack, such as by protecting the battery from operating outside its safe operating area, monitoring its state, calculating secondary data, reporting that data, controlling its environment, authenticating it, and/or balancing it.

Electronic components of a battery system are electrically interconnected to perform their respective functions. For example, a control unit performing the functions of the BMS is electrically connected to the battery pack to monitor the battery cells therein and to perform the further functions as described above. Electronic components of a battery system may be electrically connected via electric elements, such as a flexible printed circuit (FPC) and a printed circuit board (PCB), which may be attached to one another in a variety of ways.

For example, an FPC and a PCB may be interconnected by a plug connector attached to an end of the FPC, with the plug connector being plugged onto a corresponding plug socket on the PCB. While this type of connection between the FPC and the PCB is visually inspectable, that is, whether or not the connection is correctly achieved can be determined by the (naked) eye, such a plug connector is relatively expensive. Also, mechanical issues may arise.

As another example, an FPC and a PCB may be interconnected by hot bar soldering, in which conductive stripes of the FPC are directly soldered onto corresponding plating portions on the PCB. This process is relatively slow and prone to error because it is difficult to precisely position the FPC and the PCB relative to one another and to keep the FPC and the PCB in the required position for the duration of the soldering process. Also, electrical contact elements of the FPC and the PCB may be directly connected via crimping contacts, but this is a complex and error-prone procedure.

### SUMMARY

According to embodiments of the present invention, a method for electrically connecting a first electronic component of a battery system with a second electronic component of the battery system is provided, and a respective battery system exhibiting low-cost, fast, and reliable electrical connection of electronic components is also provided.

The present disclosure is defined by the appended claims and their equivalents. The description that follows is subject to this limitation. Any disclosure lying outside the scope of the claims and their equivalents is intended for illustrative as well as comparative purposes.

According to an embodiment of the present disclosure, a method for electrically connecting a first electronic component of a battery system with a second electronic component of the battery system is provided. The first electronic component includes a flexible printed circuit (FPC) including: one or more pins formed by folding a connection portion of the FPC; and one or more conductive strips on an outer surface of the folded connection portion. The second electronic component includes a printed circuit board (PCB) including: one or more through-holes, each configured to receive one of the pins of the FPC and extending through the PCB from a first side of the PCB to a second side of the PCB. The PCB further includes, at each of the through-holes, an electrically conductive plating on the second side of the PCB adjacent to the through-hole. The method includes: attaching the FPC to the first side of the PCB such that each of the pins of the FPC is received by a corresponding one of the through-holes in the PCB; and soldering each of the pins of the FPC to the respective conductive plating of the PCB at the second side of the PCB to electrically interconnect the FPC and the PCB.

According to another embodiment of the present disclosure, a battery system includes a plurality of battery cells, a first electronic component including a flexible printed circuit (FPC) including one or more pins formed by folding a connection portion of the FPC; and a second electronic component electrically connected to the first electronic component and including a printed circuit board (PCB) having one or more through-holes, each configured to receive one of the pins of the FPC. The connection portion has a slot between adjacent ones of the pins.

Further aspects and features of the present disclosure can be learned from the dependent claims and/or the following description.

### BRIEF DESCRIPTION OF THE DRAWINGS

Aspects and features of the present disclosure will become apparent to those of ordinary skill in the art by describing, in detail, embodiments thereof with reference to the attached drawings, in which:

FIG. 1 is a schematic side view of a battery system according to an embodiment.

FIG. 2 is a schematic top section of an FPC of the battery system shown in FIG. 1 according to an embodiment.

FIG. 3 is a schematic perspective view of a PCB of the battery system shown in FIG. 1 according to an embodiment.

FIG. 4A is a schematic top view of the FPC shown in FIG. 1 with its connection portions being folded to a U-shape.

FIG. 4B is a schematic perspective of the FPC shown in FIG. 4A.

FIG. 5 is a schematic perspective view of the FPC shown in FIGS. 4A and 4B and the PCB shown in FIG. 3 in an interconnected state according to an embodiment.

### DETAILED DESCRIPTION

Reference will now be made, in detail, to embodiments, examples of which are illustrated in the accompanying drawings. Aspects and features of the embodiments, and implementation methods thereof, will be described with reference to the accompanying drawings. The present disclosure may, however, be embodied in various different forms and should not be construed as being limited to the embodiments illustrated herein. Rather, these embodiments are provided as examples so that this disclosure will be thorough and complete and will fully convey the aspects and features of the present disclosure to those skilled in the art.

Accordingly, processes, elements, and techniques that are not considered necessary for those having ordinary skill in the art to have a complete understanding of the aspects and features of the present disclosure may not be described or may be briefly described.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

As used herein, the term “substantially,” “about,” and similar terms are used as terms of approximation and not as terms of degree and are intended to account for the inherent deviations in measured or calculated values that would be recognized by those of ordinary skill in the art. Further, if the term “substantially” is used in combination with a feature that could be expressed using a numeric value, the term “substantially” denotes a range of +/−5% of the value centered on the value.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The control unit, controller, and/or any other relevant devices or components according to embodiments of the present disclosure described herein may be implemented utilizing any suitable hardware, firmware (e.g., an application-specific integrated circuit), software, and/or a suitable combination of software, firmware, and hardware. For example, the various components of the control unit may be formed on one integrated circuit (IC) chip or on separate IC chips. Further, the various components of the control unit may be implemented on a flexible printed circuit film, a tape carrier package (TCP), a printed circuit board (PCB), or formed on a same substrate as the control unit. Further, the various components of the control unit may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the exemplary embodiments of the present disclosure.

According to embodiments of the present disclosure, a method for electrically connecting a first electronic component of a battery system with a second electronic component of the battery system is provided. According to another embodiment of the present disclosure, a battery system including the first electronic component and the second electronic component electrically interconnected via the method is provided. Thus, the method, according to embodiments of the present disclosure, is used to manufacture (e.g., is part of the manufacturing process of) the battery system according to embodiments of the present disclosure. In the following, the method and the battery system will be described together because details/embodiments described with respect to the method also apply to the battery system and vice versa.

The first electronic component and/or the second electronic component may be electronic components of the battery system that are configured for monitoring the battery cells of the battery system. For example, the first electronic component may be a control unit (e.g., a controller) configured to perform the functions of (e.g., configured to act as) a battery management system (BMS), as explained in the above section, and the second electronic component may be the battery pack including the battery cells. Of course, it may also be the other way around.

The first and second electronic components are electrically interconnected via the method, in other words, an electrical connection between the first and second electronic components is established. When this electrical connection is established, the first and/or second electronic components can perform their intended functions. For example, the BMS may then monitor the battery cells, for example, monitoring a state, charging status, and/or a temperature of the battery cells as described above.

The first electronic component, according to embodiments of the present disclosure, includes a flexible printed circuit (FPC). The FPC may be a flexible printed circuit board (FPCB). The FPC includes at least one connection portion and at least one conductive strip disposed on a surface of the connection portion. A plurality of conductive strips may be disposed on the surface of the connection portion. The connection portion is an intrinsic (or integral) part of the FPC rather than a separate element. The connection portion may be a part of a substrate forming the FPC or, in other words, may be part of the board forming the FPCB. The conductive strips may be free ends of conductive paths/tracks of the FPC. In a first state, the connection portion and, thus, the conductive strips are flat, in other words, they extend along a plane/flat surface. In a second state, the connection portion and, thus, the conductive strips are folded (or bent) into a U-shape so that they no longer extend along the plane/flat surface. In the second state, that is, when folded, the connection portion and conductive strips form one or more pins at where the conductive strips are disposed on an outer surface of the U-shaped connection portion. The FPC may include multiple such pins separated by slots in the FPC, and each pin may include one conductive strip as described in more detail below.

The second electronic component, according to embodiments of the present disclosure, includes a printed circuit board (PCB). The PCB may be a rigid (e.g., non-flexible) PCB. The PCB has at least one through-hole that is configured to receive the at least one pin of the FPC. The PCB may have a plurality of through-holes, and each of the through-holes may be configured to receive a respective one of the pins of the FPC. The through-holes may be arranged in one or more rows. The one or more through-holes in the PCB extend through the PCB from a first side of the PCB to a second side of the PCB, and thus, each through-hole forms a passage through the PCB. Electrically conductive platings are disposed adjacent to each of the through-holes on the second side of the PCB. The conductive platings may be metal platings.

To establish the electrical interconnection between first and second electronic components, the FPC of the first electronic component is electrically connected to the PCB of the second electronic component. This may be achieved via the method according to embodiments of the present disclosure.

In a first step of the method, according to an embodiment of the present disclosure, the FPC and the PCB are attached to one another such that each of the pins of the FPC is received by (e.g., is accommodated in or extends through) one of the through-holes in the PCB. In other words, the pins of the FPC are inserted into the corresponding through-holes in the PCB. When the FPC is attached to the PCB, the pins extend through the respective through-hole from the first side to the second side such that a tip of each of the pins protrudes above the second side of the PCB. As explained, the conductive strips of the pins are not separate elements but are an intrinsic part of the FPC, such as free ends of conductive paths/tracks of the FPC. Thus, in the first step the FPC is, with its pins, directly inserted into the PCB without the need for a separate connector, such as a plug connector. Rather, the connection portion with the conductive strips is folded, or pre-folded, during manufacture of the FPC so that the pins and, thus, an intrinsic or one-piece connector is formed for connecting to the PCB. In other words, the pins are formed by bending a part of the FPC.

In a second step of the method, according to an embodiment of the present disclosure, which follows the first step, each of the pins of the FPC is soldered to the respective conductive plating of the PCB at the second side of the PCB. Thus, for each pin, an electrical connection is established between the conductive strip extending along the outer surface of the U-shaped pin and the adjacent conductive plating. In other words, the tip of the respective pin extending above the second side of the PCB is soldered to the PCB in that the solder electrically connects the conductive strip of the pin of the FPC to the conductive plating of the PCB. As a result, the FPC and the PCB and, therefore, the first electronic component and the second electronic component, are electrically connected to one another.

The electrical connection between the first electronic component and the second electronic component is achieved quickly because the FPC merely is inserted with its pins into the corresponding through-holes in the PCB and the pins are soldered. No additional part, such as a plug connector, is needed. Rather, the connections portion with its pins forms an intrinsic (or one-piece) connector with the FPC. Further, the pins and their electrical connection to the PCB can be easily visually inspected to ensure the connection is correctly/sufficiently achieved. The soldering step is simplified because the pins are not merely placed on the platings but are, due to the through-holes, precisely arranged relative to the platings. Thus, the soldering may be performed quicker and with fewer or no errors. The electrical connection achieved via the method and battery system according to embodiments of the present disclosure is therefore low-cost, fast, and reliable.

According to an embodiment, the method further includes, before the attaching of the FPC to the PCB, folding the connection portion, with the one or more conductive strips extending along its surface, into a U-shape such that the one or more conductive strips extend along the outer surface of the resulting U-shaped connection portion. The U-shaped connection portion with the one or more conductive strips thus forms the one or more pins. In other words, the FPC may include the one or more conductive strips on a surface of the connection portion, and the method may include: folding the connection portion of the FPC into a U-shape such that the conductive strips extend along the outer surface of the resulting U-shaped connection portion. The U-shaped connection portion with the one or more conductive strips thus forms the one or more pins. Thus, the above-described folding of the connection portion may be part of the method according to embodiments of the present disclosure. This folding of the connection portion allows for forming the pins as an intrinsic/one-piece element of the FPC and, therefore, provides a simple and effective way of configuring/forming the pins and the connection to the PCB. No separate connector, such as a plug connector, is needed for electrically connecting the FPC and the PCB.

According to an embodiment, the soldering includes selective wave soldering. Selective wave soldering may provide a simple and reliable connection between the conductive strips of the pins and the conductive platings of the PCB. Such a soldering is one of the most low-cost, fast, and reliable soldering methods, for example, compared to hot bar soldering.

According to an embodiment, the connection portion includes multiple connection arms, and one of the conductive strips is disposed on the surface of each of the connection arms. The connection arms are separated from one another via slots in the FPC, and each of the connection arms with its conductive strip forms one of the pins. In other words, the connection portions may include a plurality of connections arms, and neighboring connection arms are spaced apart from each other via a slot in the FPC (e.g., in the substrate/board of the FPC). One of the conductive strips of the FPC extends along each of the connection arms. During the folding of the connection portion, each of the connection arms is folded into a U-shape as well such that the conductive strip of the respective connection arm extends along the outer surface of the resulting U-shaped connection arm. Each of the connection arms forms, in the folded position, that is, when U-shaped, one of the pins with its conductive stripe extending along the outer surface of the U-shaped connection arm and, thus, of the pin. According to an embodiment, the PCB has a plurality of the through-holes, with the number of the through-holes corresponding to the number of pins. The through-holes in the PCB may be spaced apart from each other by the same distance the connection arms and, therefore, the pins, are spaced apart from one another. When attaching the FPC to the PCB, each of the pins of the FPC may then be received by one of the through-holes in the PCB. This may allow for a simple connection between the FPC and the PCB. The separation of the pins may ensure that, when soldering a pin to the respective conductive plating, an electrical connection is made only between said pin and conductive plating and not mistakenly between neighboring pins/platings.

According to an embodiment, the connection portion of the FPC includes a first connection portion extending from a first end of the FPC and a second connection portion extending from a second end of the FPC opposite to the first end. One or more first pins of the one or more pins are formed by folding the first connection portion into a U-shape, and one or more first conductive strips of the one or more conductive strips are disposed on a surface of the first connection portion along the outer surface of the U-shaped first connection portion. One or more second pins of the one or more pins are formed by folding the second connection portion into a U-shape, and one or more second conductive strips of the one or more conductive strips are disposed on a surface of the second connection portion along the outer surface of the U-shaped second connection portion. In other words, the FPC may include more than one connection portion, and in such an embodiment, each of the connection portions may form at least one pin. The connection portions may include a plurality of connection arms, as described above, so that each connection portion may form a plurality of pins. For example, a first number of pins of the one or more pins may be formed by folding the first connection portion with the connection arms into a U-shape such that one conductive strip extends along the outer surface of each of the U-shaped connection arms/pins. The FPC may include a third connection portion extending from a third end of the FPC, with the third end arranged between the first end and the second end. Correspondingly, the PCB may include one or more first through-holes of the one or more through-holes at a first end of the PCB and one or more second through-holes of the one or more through-holes at a second end of the PCB. The first through-hole may be configured to receive the first pin, and the second through-hole may be configured to receive the second pin. According to this embodiment, the FPC and the PCB are interconnected via pins of multiple connection portions at different positions/ends of the FPC and PCB. When attaching the FPC to the PCB, the first pins and first through-holes and the second pins and second through-holes are aligned and connected as explained above. The FPC and the PCB may, thus, be aligned to each other, for example, in a mistake-proof (“poka-yoke”) manner. This ensures a correct connection between the FPC and the PCB. The pins and through-holes, according to embodiments of the present disclosure, allow for a low-cost, fast, and reliable connection between the electronic components and for a battery system including the same.

According to an embodiment, the attaching of the FPC and the PCB includes adhering the FPC and PCB together before soldering. In such an embodiment, the FPC may include an adhesive at its surface, for example, at the side of the FPC that faces the PCB. Alternatively or additionally, the PCB may include an adhesive at its first side, for example, at the side of the PCB that faces the FPC. Such an adhesive may include s double-sided tape and/or glue. The FPC and PCB may be securely attached to one another by the adhesive before the soldering, which eases the soldering.

Another embodiment of the present disclosure provides an electric vehicle including a battery system as described above, that is, a battery system provided by the method as described above.

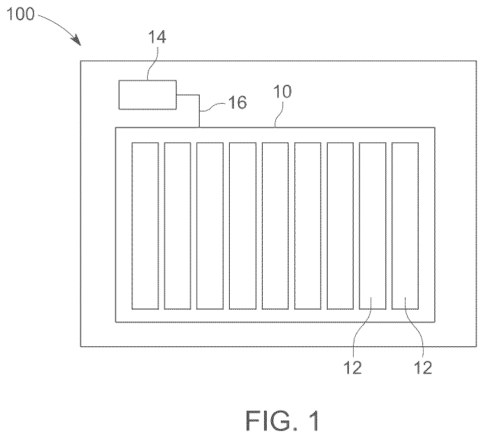

FIG. 1 is a schematic illustration of a battery system 100 according to an embodiment. The battery system 100 includes a battery pack 10 with a plurality of battery cells 12. The battery cells 12 are monitored by a control unit (e.g., a controller) 14, which acts as (e.g., which provides the functions of) a battery management system (BMS). The control unit 14 and the battery pack 10 are electrically interconnected via an electrical connection 16.

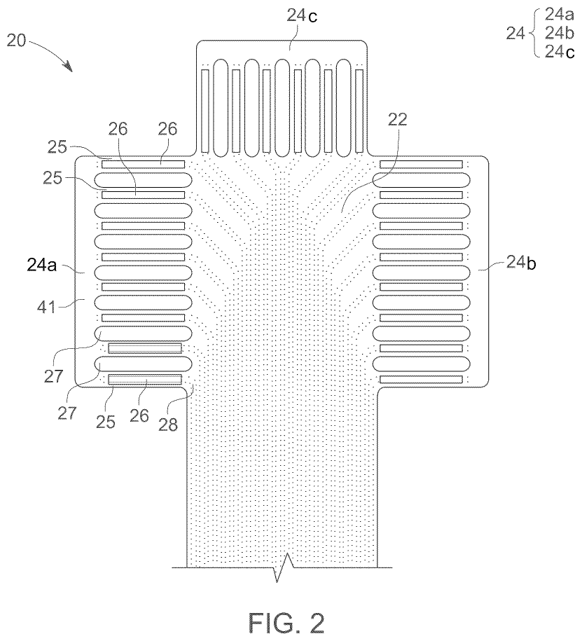

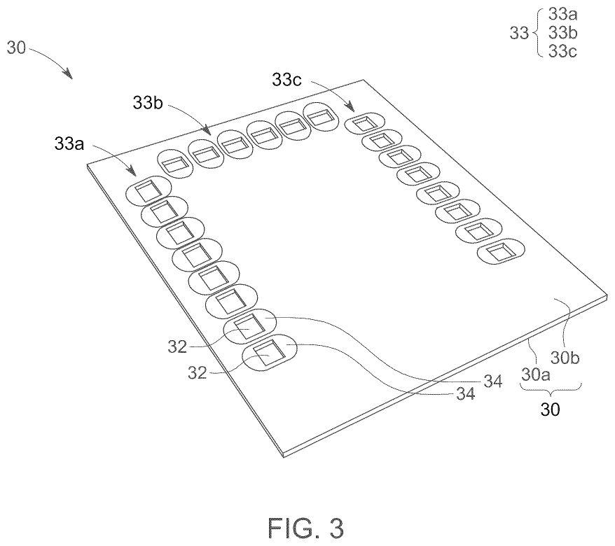

The electrical connection 16 is established by connecting a flexible printed circuit (FPC) 20 (see, e.g., FIG. 2) of the control unit 14 to a rigid printed circuit board (PCB) 30 (see, e.g., FIG. 3) of the battery pack 10. In some embodiments, the electrical connection 16 may be established by connecting an FPC of the battery pack 10 to a PCB of the control unit 14.

Referring to FIG. 2, the FPC 20 has a central portion 22 and three connection portions 24—a first connection portion 24a, a second connection portion 24b, and a third connection portion 24c. The connection portions 24 extend from different sides and/or ends of the central portion 22. The first connection portion 24a extends from a first end of the FPC 20, the second connection portion 24b extends from a second end of the FPC 20 opposite the first end, and the third connection portion 24c extends from a third end of the FPC 20, the third end being arranged between the first end and the second end. The third end of the FPC 20 faces in a direction approximately 90° with respect to the directions in which the first and second ends of the FPC 20.

Each of the connection portions 24 includes multiple connection arms 25 having a conductive strip 26 thereon. Neighboring connection arms 25 are separated from one another via slots (e.g., openings or elongated openings) 27 formed between the connection arm 25. When forming the slots 27, an end face portion 41 of each of the connection portions 24 remains (e.g., the slots 27 do not extend to an edge of the respective connection portion 24). The end face portion 41 may provide stability to the connection portions 24 because it keeps (or forms) a bridge between the connection arms 25 at a free end of the connection portion 24. The conductive strips 26 are endings of conductive paths/tracks 28 of the FPC 20 (see, e.g., FIG. 2).

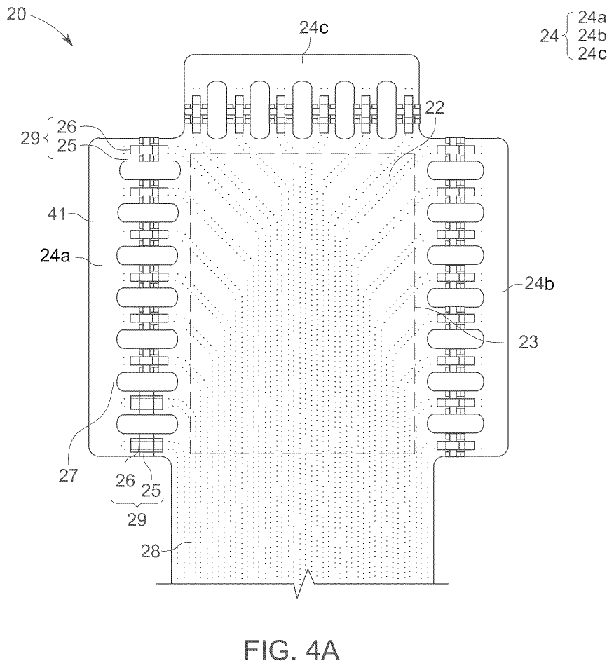

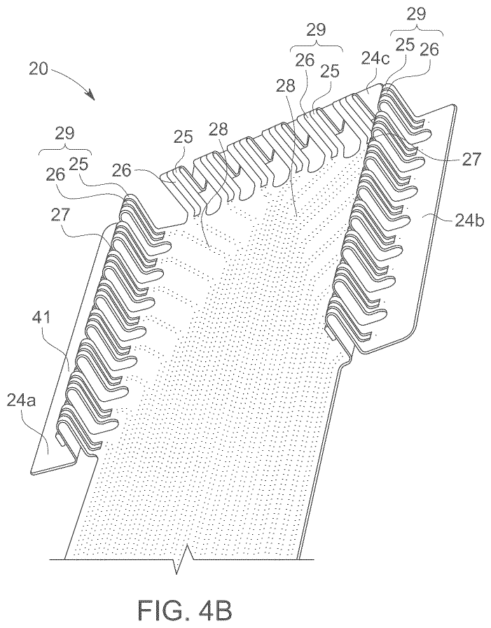

In FIG. 2, the connection portions 24 are shown in a first state in which the conductive strips are 24 extend along a plane or flat surface, that is, along the plane on which the central portion 22 extends. According to an embodiment, in a second state, the connection portions 24 and, thus, their connection arms 25 with the conductive strips 26, are folded to protrude, for example, into a U-shape (see, e.g., FIGS. 4A and 4B). In the second state, that is, when folded, each of the U-shaped connection arms 25 forms, together with its conductive strip 26, a pin 29 at where the conductive strip 26 is disposed on an outer surface of the U-shaped connection arm 25. As can be seen in, for example, FIG. 4B, the pins 29 extend above an upper surface of the FPC 20. The connection portions 24 can be folded during manufacture of the FPC 20 or during assembly of the FPC 20 and PCB 30 before attaching the FPC 20 to the PCB 30. When the connection arms 25, together with its conductive strips 26, are folded into a U-shape, the connection arms 25 can be easily folded by the slots 27 arranged between the connection arms 25, that is, between the pins 29.

FIG. 3 shows the PCB 30. The PCB 30 includes multiples rows 33 of through-holes (e.g., openings) 32. A first row 33a includes a number of (e.g., a first group of) through-holes 32 corresponding to the number of pins 29 on (or formed by) the first connection portion 24a, a second row 33b includes a number of (e.g., a second group of) through-holes 32 corresponding to the number of pins 29 on the second connection portion 24b, and a third row 33a includes a number of (e.g., a third group of) through-holes 32 corresponding to the number of pins 29 on the third connection portion 24c. The through-holes 32 are each configured to receive one of the pins 29 of the FPC 20. The through-holes 32 extend through the PCB 30 from a first side 30a of the PCB 30, which is the bottom side in FIG. 3, to a second side 30b of the PCB 30, which is the top side in FIG. 3. Each of the through-holes 32 is surrounded by (e.g., is surrounded along its periphery by) an electrically conductive plating 34 on the second side 30b. However, the present disclosure is not limited thereto. In other embodiments, the first side of the PCB 30 may be the top side in FIG. 3, and the second side of the PCB 30 may be the bottom side in FIG. 3 as long as the first side of the PCB 30 is the opposite to the second side thereof.

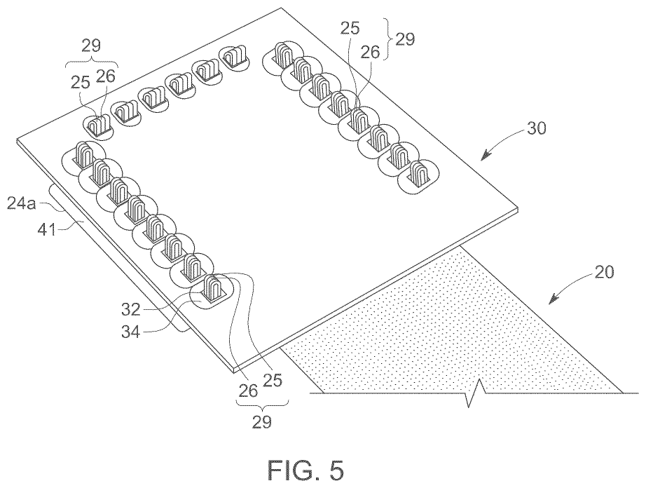

When connecting the FPC 20 to the PCB 30, the FPC 20 is attached to the first side 30a of the PCB 30 such that each of the pins 29 of the FPC 20 is received by (e.g., is accommodated in or by) one of the through-holes 29 in the PCB as shown in, for example, FIG. 5. In this attached state, each of the pins 29 extends through its respective through-hole 32 such that a tip of the pin 29 extends above the second side 30b of the PCB 30. To securely attach the FPC 20 to the first side 30a of the PCB 30, the upper surface of the FPC 20 and/or the first side 30a of the PCB 30 has an adhesive area 23. Thus, the FPC 20 may stick to (e.g., may be adhered to) the PCB 30. In some embodiments, the conductive plating 34 may be provided at (e.g., may be provided around) every through-hole 32 of the PCB 30 as shown in, for example, FIG. 3.

After the attaching, each of the pins 29 of the FPC 20 is soldered to the respective conductive plating 34 of the PCB 30 at the second side 30b of the PCB 30. For example, the soldering may be selective wave soldering. Thereby, the FPC 20 and PCB 30, and as a result the control unit 14 and the battery pack 10, are electrically interconnected.

The electrical connection between the control unit 14 and the battery pack 10 is, thusly, achieved in a simple, reliable, and quick manner. The FPC 20 is simply inserted with its pins 29, after the connection portions 24 have been folded, into the corresponding through-holes 32 in the PCB 30 and the pins 29 are soldered to the PCB 30. No additional part, such as a plug connector, is needed. Rather, the connections portions 24 with their pins 29 form an intrinsic (or one-piece) connector with the FPC 20. The pins 29 and their electrical connection to the PCB 30, for example, the soldering between the conductive strips 26 and the conductive plating 34, can be easily visually inspected by a person or machine to ensure the connection is correctly/sufficiently achieved. Because the connection portions 24 are arranged at different endings of the FPC 20 and the rows 33 of through-holes 32 are arranged at corresponding endings of the PCB 30, the FPC 20 and the PCB 30 can only be attached to one another in one possible alignment, which makes the assembly mistake-proof. Because the pins 29 are precisely placed in (e.g., are aligned by) their corresponding through-holes 32, the subsequent soldering is simplified. Thus, the soldering may be performed quicker and with fewer or no errors.

Some Reference Numerals

| | |
|---|---|
| 10 | battery pack |
| 12 | battery cells |
| 14 | control unit |
| 16 | electrical connection |
| 20 | FPC |
| 22 | central portion of FPC |
| 23 | adhesive area |
| 24 | connection portions |
| 24a | first connection portion |
| 24b | second connection portion |
| 24c | third connection portion |
| 25 | connection arms |
| 26 | conductive strips |
| 27 | slots |
| 28 | conductive paths/tracks |
| 30 | PCB |
| 32 | through-holes |
| 33 | row of through-holes |
| 34 | conductive platings |
| 41 | end face portion |
| 100 | battery system |

What is claimed is:

1. A method for electrically connecting a first electronic component of a battery system with a second electronic component of the battery system, the first electronic component comprises a flexible printed circuit (FPC) comprising: a pin formed by folding a connection portion of the FPC; and a conductive strip on an outer surface of the folded connection portion, the second electronic component comprising a printed circuit board (PCB) having a through-hole extending from a first side of the PCB to a second side of the PCB and configured to receive the pin of the FPC, the PCB comprising an electrically conductive plating on the second side of the PCB adjacent to the through-hole, the method comprising:
attaching the FPC to the first side of the PCB such that the pin of the FPC is received in the through-hole in the PCB; and
soldering the pin of the FPC to the conductive plating on the PCB to electrically interconnect the FPC and the PCB.

2. The method as claimed in claim 1, further comprising, before the attaching of the FPC to the PCB, folding the connection portion with the conductive strip extending along its surface into a U-shape such that the conductive strip extends along an outer surface of the folded U-shaped connection portion,
wherein the U-shaped connection portion with the conductive strip forms the pin.

3. The method as claimed in claim 1, wherein the soldering comprises selective wave soldering.

4. The method as claimed in claim 1, wherein the connection portion comprises a plurality of connection arms,
wherein one of the conductive strips is on a surface of each of the connection arms, the connection arms being separated from one another via slots in the FPC, and
wherein each of the connection arms with its corresponding one of the conductive strips forms one of the pins.

5. The method as claimed in claim 1, wherein the connection portion of the FPC has a first connection portion extending from a first end of the FPC, and a second connection portion extending from a second end of the FPC opposite to the first end,
wherein a first pin is formed by folding the first connection portion into a U-shape, a first conductive strips being on a surface of the first connection portion along an outer surface of the U-shaped first connection portion, and
wherein a second pin is formed by folding the second connection portion into a U-shape, a second conductive strip being on a surface of the second connection portion along an outer surface of the U-shaped second connection portion.

6. The method as claimed in claim 1, wherein the attaching of the FPC and the PCB comprises adhering the FPC and PCB together before the soldering.

7. A battery system comprising:
a plurality of battery cells;
a first electronic component comprising a flexible printed circuit (FPC), the FPC comprising a plurality of pins formed by folding a connection portion of the FPC; and
a second electronic component electrically connected to the first electronic component, the second electronic component comprising a printed circuit board (PCB), the PCB having a plurality of through-holes respectively configured to receive one of the pins of the FPC,
wherein the connection portion has a slot between adjacent ones of the pins.

8. The battery system as claimed in claim 7, wherein the connection portion comprises a plurality of connection arms separated from one another via the slot.

9. The battery system as claimed in claim 8, wherein the connection portion has an end face portion extending between the connection arms at a free end of the connection portion.

10. The battery system as claimed in claim 7, wherein the FPC further comprises a plurality of conductive strips on an outer surface of the connection portion.

11. The battery system as claimed in claim 7, wherein the PCB comprises a plurality of electrically conductive platings respectively adjacent to the through-holes at a side of the PCB.

12. The battery system as claimed in claim 11, wherein the each of the pins of the FPC is soldered to a corresponding one of the electrically conductive platings of the PCB at the side of the PCB.

13. An electric vehicle comprising the battery system as claimed in claim 7.
